(19) United States
(12) Patent Application Publication
(10) Pub. No.: US 2022/0349749 A1
(43) Pub. Date: Nov. 3, 2022

(54) Active Thin-Film Charge Sensor Element

(71) Applicants: IMEC VZW, Leuven (BE); Katholieke Universiteit Leuven, KU LEUVEN R&D, Leuven (BE)

(72) Inventors: Aris Siskos, Heverlee (BE); Florian De Roose, Rumst (BE); Kris Myny, Heusden-Zolder (BE); Wim Dehaene, Kessel-Lo (BE)

(21) Appl. No.: 17/723,970

(22) Filed: Apr. 19, 2022

(30) Foreign Application Priority Data
Apr. 29, 2021 (EP) 21171195.7

(51) Int. Cl. G01J 1/44; H03F 3/16; H04N 5/3745

(52) U.S. Cl. CPC G01J 1/44; H03F 3/16; H04N 5/37457; H04N 5/353

(57) ABSTRACT

A charge sensor element includes a charge collecting detector configured to generate an intensity signal indicative of an amount of charge at an internal charge sensor element node, an amplifier transistor that is electrically connected to the internal charge sensor element node and configured to amplify the intensity signal, and a reset transistor that is electrically connected to the internal charge sensor element node and configured to reset the intensity signal. The amplifier transistor or the reset transistor includes a front gate and a back gate that are configured to control the amplifier transistor or the reset transistor.

### CROSS-REFERENCE TO RELATED APPLICATIONS

The present application is a non-provisional patent application claiming priority to European Patent Application No. 21171195.7, filed Apr. 29, 2021, the contents of which are hereby incorporated by reference.

### FIELD OF THE DISCLOSURE

The disclosure relates to an active thin-film charge sensor element, more specifically to an active thin-film charge sensor element comprising an amplifier transistor and/or a reset transistor, wherein at least either the amplifier transistor or reset transistor comprises a front gate and a back gate, and wherein the front and back gates are configured to control the amplifier transistor or reset transistor.

### BACKGROUND

To drive sensor elements of a charge-based sensor, such as pixels of an imager, sensor element circuits (pixel circuits) are included in the backplane of the sensor, e.g. imager.

Large charge-based sensors, such as 10 cm×10 cm image sensors, have previously used passive charge sensor elements (pixel sensors). However, passive pixel sensors have low conversion gain and low noise performance. Therefore, active pixel sensors (active charge sensor elements) are often preferred.

When using active charge sensor elements in a charge-based sensor array, sensor element circuits are typically needed for driving the charge sensor elements. Active charge-based sensor topologies use an amplifier to increase the conversion gain of the system. These topologies have either a voltage output or a current output and hence are called Voltage-Mode (VM) or Current-Mode (CM) charge sensor elements.

Known topologies are based on different configurations, all having a charge collecting detector and at least one amplifying transistor. The topology of the active charge sensor element circuit may be any of a two-transistor (2T), three-transistor (3T), or a four-transistor (4T) topology.

The use of multiple transistors in the charge sensor element results in a certain charge sensor element area for physically encompassing all the components, e.g. a charge collecting detector (such as photodetector) and transistors, and at the same time amplification by the amplification transistor must be large enough to generate a gain between the intensity signal generated by the charge collecting detector and the data line signal.

Additionally, the charge sensor element area determines the number of active charge sensor elements that can fit in the charge-based sensor having a pre-fixed size, i.e. the charge sensor element density, for example, the so-called pixel pitch of an image sensor. The charge sensor element density, or the number of active charge sensor elements in the charge-based sensor per unit area, will thus also determine a possible highest resolution of the charge-based sensor.

Thus, there is a need for a reduced charge sensor element area and thus a higher resolution fixed size charge-based sensor.

### SUMMARY

It is potential benefit of the disclosure to alleviate one or more of the above-identified issues. In particular, it is a potential benefit to provide a small area charge sensor element size.

The use of thin-film technology for manufacturing sensors is of interest in particular when a flexible and/or large sensor is desired. The most common applied thin-film topology is the passive charge-based sensor, because the performance of transistors has generally not been sufficient to enable use of active charge-based sensors. When using a passive sensor topology, an external charge-sense amplifier part of a periphery is connected to an output of a data line. Such topology increases complexity of the charge-based sensor. Furthermore, noise performance is typically low since the conversion gain is low. It therefore can be required to either detect a higher sensor signal via the charge collecting detector, e.g. detecting a higher light intensity by a photodetector, or to increase the size of the passive sensor element so that the sensing area will be increased.

A particular technique using an active charge sensor element will be discussed herein and is based on the use of dual-gate transistors that consist of a front gate (FG) and a back gate (BG) in thin-film technology resulting in the active thin-film charge sensor element comprising dual gate thin-film transistors.

Hence, throughout this disclosure the use of the back gate generally does not correspond to a bulk gate in transistors formed on a wafer, in which the bulk gate may sometimes confusingly be referred to as the back gate. In the present disclosure, the thin-film transistors are not formed on a bulk material and the front gate and back gate provide potentials on opposite sides of a thin-film transistor, which differs from a potential provided to a bulk gate, as is in other MOSFET based sensors.

The thin-film transistor may comprise a thin film of semiconducting material, a source, a drain, and a gate. The gate may control a current from the source to the drain through the thin film. The current may be passed laterally through the thin film.

The thin-film transistor may be free of a semiconducting substrate. The thin-film transistor may instead be attached to a supporting but non-conducting substrate such as an insulating substrate, e.g. a glass substrate, an oxide substrate, or a polymer substrate. The thin-film transistor may be grown or deposited on the substrate.

Semiconducting material in a thin-film transistor may be e.g. amorphous indium-gallium-zinc-oxide (a-IGZO) or other amorphous oxide semiconductors, amorphous silicon, low-temperature polycrystalline silicon (LTPS), or organic semiconducting material.

The structural order of the material of the thin-film may be lower than single crystalline structural order. For example, the structural order of the material of a thin-film integrated circuit including thin-film transistors may be amorphous structural order, microcrystalline structural order, or polycrystalline structural order.

The film thickness of the thin-film may depend on the embodiment. In some embodiments, the film thickness of the thin-film transistors may lie in a range of 1 nm to 100 μm. In some embodiments, the film thickness of the thin-film transistors may lie in a range of 0.5 μm to 50 μm. For example, in IGZO the thin-film thickness is between 10 nm-30 nm, such as 12 nm or 24 nm.

According to a first aspect, there is provided an active thin-film charge sensor element comprising, a charge collecting detector configured to detect a predetermined physical quantity and generate a corresponding intensity signal at an internal charge sensor element node, an amplifier transistor, the amplifier transistor comprising at least one gate that is electrically connected to the charge collecting detector at the internal charge sensor element node, and configured to amplify the intensity signal, a reset transistor, the reset transistor is electrically connected to the internal charge sensor element node and configured to reset the intensity signal, and wherein at least one of the amplifier transistor or reset transistor comprises a front gate and a back gate and wherein the front and back gates are configured to control the amplifier transistor or reset transistor.

According to a second aspect, there is provided a method for controlling an active thin-film charge sensor element comprising the steps of detecting a predetermined physical quantity with a charge collecting detector and generating a corresponding intensity signal at an internal charge sensor element node, amplifying the intensity signal by an amplifier transistor comprising at least one gate that is electrically connected to the charge collecting detector at the internal charge sensor element node, resetting the intensity signal by a reset transistor, the reset transistor is electrically connected to the internal charge sensor element node, and wherein the amplifying and/or resetting is controlled by a front gate and a back gate of the amplifier transistor or reset transistor.

Thanks to the use of the thin-film dual-gate transistors that comprise a front gate and a back gate, an increased performance of the transistor may be achieved. The dual-gate transistor may provide an increased gain with a same amount of transistor area compared to a transistor having only a single gate.

Throughout this application the front gate and back gate are used to describe two different gates of the transistors that follows a most common electrical signal path in a pixel. However, it should also be understood that the front gate and back gate are interchangeable.

Thus, the thin-film dual-gate transistor having the front gate and the back gate may be utilized in order to provide the improved gain of the thin-film dual-gate transistor compared to the single-gate transistor and/or may be utilized in order to have a smaller area of the thin-film dual-gate transistor for a given gain. A smaller area of the thin-film dual-gate transistor may be advantageous in order to decrease a size of the thin-film active charge sensor element, which may enable a small charge sensor element pitch to be used and enable a charge-based sensor with a high resolution.

Signals on the front and/or back gates of the thin-film dual-gate transistor may act together for controlling the transistor. Whereas the signal on the front gate may be based on a desired functionality of the thin-film active sensor element, e.g. the signal on the front gate of the amplifier transistor may be the intensity signal, the signal on the back gate may be provided in various manners.

For instance, the back gate may be connected to the front gate, such that the signal on the back gate may follow the signal on the front gate, which may improve gain of the dual-gate transistor compared to a single-gate transistor.

According to an alternative, a fixed or adjustable voltage signal on the back gate may be provided, which voltage signal on the back gate may control an operating point of the transistor.

The electrical connection of the back-gate of the reset transistor, the select transistor, and/or the amplifier transistor can be connected externally to the individual active thin-film charge sensor elements. The external connection removes any internal connections such as a via that could be needed for the back-gate connection with the source-drain layer and could therefore simplify the production and use of the active thin-film charge sensor element.

The amplifier transistor may comprise a front gate and a back gate, and the back gate of the amplifier transistor may be electrically connected to the front gate or a select signal line.

The amplifier transistor typically is the transistor having the largest area within an active charge sensor element, since the amplifier transistor is used for amplifying the intensity signal. Therefore, it can be particularly advantageous to have an amplifier transistor comprising a front gate and a back gate, because it can allow substantially reducing the size of the amplifier transistor compared to a single-gate transistor and therefore reduce the size of the active charge sensor element.

The back gate of the reset transistor may be electrically connected to the front gate of the reset transistor. When the back gate is connected to the front gate of the reset transistor, the on-resistance of the reset transistor is improved compared to a single gate reset transistor. Thus, the size of the reset transistor can be reduced for equivalent on-resistance. Some active charge sensor elements may comprise front and back gates of the amplifier and the reset transistor.

The back gate of the amplifier transistor may be configured to be controlled by an adjustable voltage over time. By changing the voltage at the back gate, different transfer characteristics and/or output characteristics of the transistor is achieved. For instance, the current or voltage at the transistor can be regulated for a desired drain current.

Further, a select transistor may be electrically connected to the amplifier transistor. The select transistor may comprise a front gate and back gate and the front gate of the select transistor is electrically connected to the back gate of the select transistor. As with the other front and back gate connected thin-film transistors, the on-resistance of the select transistor is typically improved, resulting in improved readout and amplification of the amplified intensity signal of the charge collecting detector.

Independent of a desired mode of operation of the active thin-film charge sensor element, in a voltage-mode or current-mode, the reset and amplifier transistors are electrically connected to either an anode or cathode side of the charge collecting detector

In the current-mode a transimpedance or capacitive integration stage is generally required in the readout, which couples additional noise into the system.

Voltage-mode topologies generally have better noise performance, although the intensity signal can require a longer time to get transferred from the internal charge sensor element node or front gate of the amplifier transistor to the data line. The voltage-mode generally has additional advantages: for example, the voltage-mode active thin-film charge sensor element can directly be connected to analog-to-digital circuits, simplifying connected readout circuits.

The active thin-film charge sensor element and thus also the amplifier transistor and/or the reset transistor may be based on an etch-stop layer, back-channel etch, and/or self-aligned transistor architecture.

A plurality of the active thin-film charge sensor elements discussed above may be arranged in a charge sensor element array and/or column. The thin-film active charge sensor elements may provide an improvement in gain, which may be utilized as a smaller charge sensor element area for a given gain. Hence, in an array, the active thin-film charge sensor elements may enable a high-resolution charge-based sensor, where the charge sensor element pitch should be small. Further, the use of thin-film technology may also enable large-size charge-based sensors.

The active thin-film charge sensor element may be configured for detecting a predetermined physical quantity (such as for example electro-magnetic radiation, a charge, a temperature change, a capacitance, or mechanical stress), with the charge collecting detector (for example an electromagnetic detector, an electric detector, a pyroelectric detector, or a piezoelectric detector), and generating a corresponding intensity signal at an internal pixel node. The intensity signal is amplified by the amplifier transistor connected to the charge collecting detector at the internal charge sensor element node by providing the intensity signal on one of a front gate or a back gate of the amplifier transistor such that the intensity signal is amplified.

Throughout this application, the term electromagnetic radiation may refer to visible light, infrared radiation, ultraviolet, and/or X-rays. The corresponding electromagnetic detector may then be any type of detector that is configured to or adapted to detect the electromagnetic radiation such as for example an image sensor, an infrared sensor, a pyroelectric sensor, and so on.

As discussed above, an interplay between signals on the front and/or back gates of the thin-film dual-gate transistor controls the amplifier transistor. The amplifier transistor may be controlled for different desired purposes and thus have different output characteristics.

The interplay between signals on the front and/or back gates of the thin-film dual-gate transistor could also be applied based on characteristics of the transistor itself such as a switch and/or amplifier, and/or to adapt a threshold voltage of the transistor.

The application of the signal on another of the back gate or the front gate of the amplifier transistor may be the application of a select signal to the back gate of the amplifier transistor. The application of the select signal on the back gate of the amplifier transistor, eliminating the select transistor, will reduce a time from the amplifier transistor to amplify the intensity signal and put the amplified signal on the data line. Hence a faster charge sensor element can be achieved.

To control the different output characteristics, the signal applied to the back gate or the front gate of the amplifier transistor may be varied over time. For example, the operation of the active thin-film charge sensor element may be controlled to alternate between an integration period or integration phase at one hand and a readout period or readout phase at the other hand, with a reset phase after each readout phase and before each integration phase. The integration period includes detection of a predetermined physical quantity. A current generated by the charge collecting detector in response to the detected physical quantity is collected on a capacitance at the internal charge sensor element node, thereby charging this internal charge sensor element node capacitance and changing the voltage (intensity signal) at the internal charge sensor element node. The intensity signal may be different at different integration times depending on a number of charges stored on the internal node capacitance resulting from the charge detecting detector. The intensity signal may be applied to the front gate of the amplifier transistor. During the integration period, the voltage (intensity signal) at the internal charge sensor element node stays below the threshold voltage of the amplifier transistor, so that there is no amplification of the intensity signal in the integration period. The readout phase includes amplification of the intensity signal (created at the internal charge sensor element node during the integration phase) by the amplifier transistor. During the readout phase, a voltage pulse (select signal) is applied to the amplifier transistor, thereby activating the amplifier transistor such that the intensity signal is amplified, and an output signal is generated.

The signal applied on the back gate of the amplifier transistor may be varied depending on a desired current and/or voltage output of the amplifier transistor or other output characteristic.

In some implementations a same signal is applied to the back gate and the front gate of the amplifier transistor for amplifying the intensity signal. The application of the same signal on the front and back gate will improve the gain of the amplifier transistor and thus result in a better signal-to-noise ratio of the amplified intensity signal.

In order to control an integration time of the intensity signal, a reset signal maybe applied to a front and back gate of the reset transistor connected at the internal charge sensor element node.

Still other objectives, features, aspects and advantages of the disclosure will appear from the following detailed description as well as from the drawings.

### BRIEF DESCRIPTION OF THE FIGURES

The above, as well as additional, features will be better understood through the following illustrative and non-limiting detailed description of example embodiments, with reference to the appended drawings.

FIG. 1 illustrates an active thin-film charge sensor element based on a voltage-mode 2T topology, according to an example.

FIG. 2 illustrates an active thin-film charge sensor element based on a voltage-mode 3T topology and back gates electrically connected to front gates, according to an example.

FIG. 3 illustrates an operation of a 2T and 3T topology for amplification of a corresponding intensity signal from a photodetector, according to an example.

FIG. 4A illustrates an active thin-film charge sensor element based on a current-mode 2T topology, according to an example.

FIG. 4B illustrates an active thin-film charge sensor element based on a current-mode 3T topology, according to an example.

FIG. 5A illustrates a 2T topology based on an active thin-film charge sensor element 10, specifically a source follower topology, according to an example.

FIG. 5B illustrates a 2T topology based on an active thin-film charge sensor element 10, specifically a source follower variation topology, according to an example.

FIG. 5C illustrates a 2T topology based on an active thin-film charge sensor element 10, specifically a common source topology, according to an example.

FIG. 5D illustrates a 2T topology based on an active thin-film charge sensor element 10, specifically a common source variation topology, according to an example.

FIG. 6 illustrates an active pyroelectric fingerprint sensor, based on the detection of temperature changes, according to an example.

FIG. 7 illustrates an active pyroelectric fingerprint sensor, based on the detection of temperature changes, according to an example.

FIG. 8 illustrates a layer stack of a pyroelectric sensor element, comprising a pyroelectric front plane and a thin-film transistor (TFT) backplane, according to an example.

FIG. 9 illustrates an array of biochemical sensor elements, according to an example.

FIG. 10 illustrates a detection mechanism of a biochemical sensor, based on the use of a marker such as a fluorescent marker or a charged marker, according to an example.

FIG. 11 shows a cross section of an ion-sensitive field-effect transistor (ISFET) that may be used for detecting a charge, according to an example.

FIG. 12A shows a cross section of a DNA field-effect transistor (DNAFET) for detecting an intrinsic DNA charge, according to an example.

FIG. 12B schematically illustrates an array of connected biomechanical sensors, according to an example.

FIG. 13 is a flowchart of a method for controlling an active thin-film charge sensor element, according to an example.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

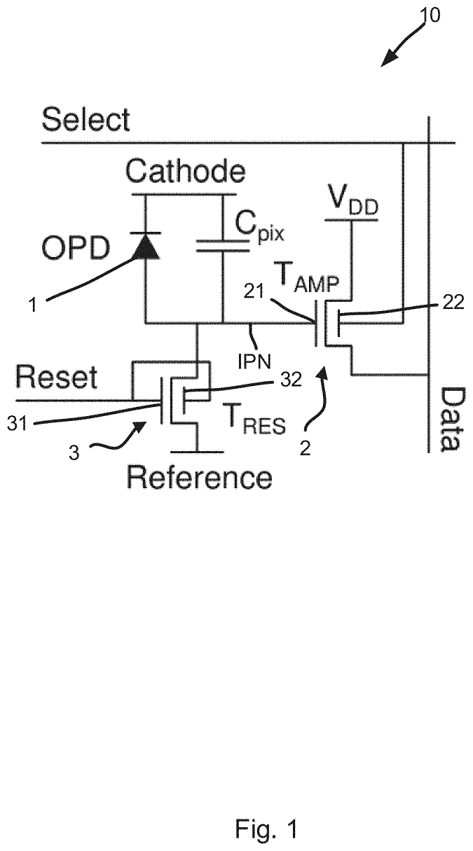

FIG. 1 illustrates an active thin-film charge sensor element 10 based on a voltage-mode 2T topology. The active thin-film charge sensor element 10 comprises an electromagnetic detector 1 (charge collecting detector 1). The electromagnetic detector 1 is configured to detect electro-magnetic radiation and generate a corresponding intensity signal at an internal charge sensor element node or internal pixel node IPN. The active thin-film charge sensor element 10 further comprises an amplifier transistor 2. The amplifier transistor 2 is electrically connected to the electromagnetic detector 1 at the internal pixel node IPN and configured to amplify the intensity signal. The active thin-film charge sensor element 10 also comprises a reset transistor 3 that is electrically connected to the electromagnetic detector 1 at the internal pixel node IPN and configured to reset the internal charge sensor element node. At least one of the amplifier transistor 2 or reset transistor 3 comprises a front gate 21, 31 and a back gate 22, 32 wherein the front gates 21, 31 and back gates 22, 32 are configured to control the amplifier transistor 2 or reset transistor 3.

The 2T topology discussed above based on thin-film technology will reduce the active thin-film charge sensor element area 10 compared to single-gate implementations, lowering the charge sensor element pitch for a given performance and/or gain, and increasing the resolution of a fixed size image sensor (charge-based sensor). The use of dual-gate thin-film transistors will also increase the conversion gain for a given size of the charge sensor element 10 compared to thin-film single-gate transistors of a same size.

Further, the 2T topology illustrated in FIG. 1 allows for applying a select signal to the back gate 22 of the amplifier transistor 2 which means that—as compared to other topologies—an extra select transistor 4 or capacitance can be omitted, thus reducing the charge sensor element pitch of the charge-based sensor. In this case when the back gate 22 of the amplifier transistor 2 is connected to the select signal, the transconductance of the amplifier transistor 2 is reduced.

The charge collecting detector 1 may be connected to the front and/or the back gate 21, 22 of the amplifier transistor 2. The charge collecting detector 1 can also be any type of charge generating detector such as a visible light detector, an infrared detector, a pyroelectric detector, an ultraviolet detector, an X-ray detector, a piezoelectric detector or a charge detector.

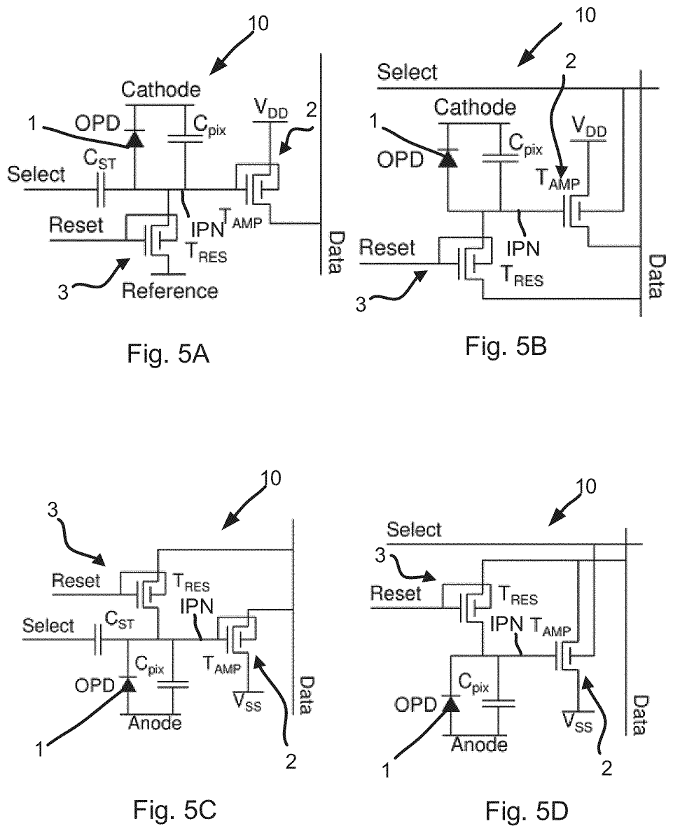

The back gate 22 of the amplifier transistor 2 may be connected to the front gate 21 (not shown in FIG. 1) or it may be connected to the select signal line (as illustrated in FIG. 1). In case the back gate 22 is connected to the front gate 21 of the amplifier transistor 2, there may be a physical connection inside the charge sensor element 10, as for example illustrated in FIG. 5A.

FIG. 1 further illustrates an electrical connection between the back gate 32 of the reset transistor 3 and the front gate 31 of the reset transistor 3.

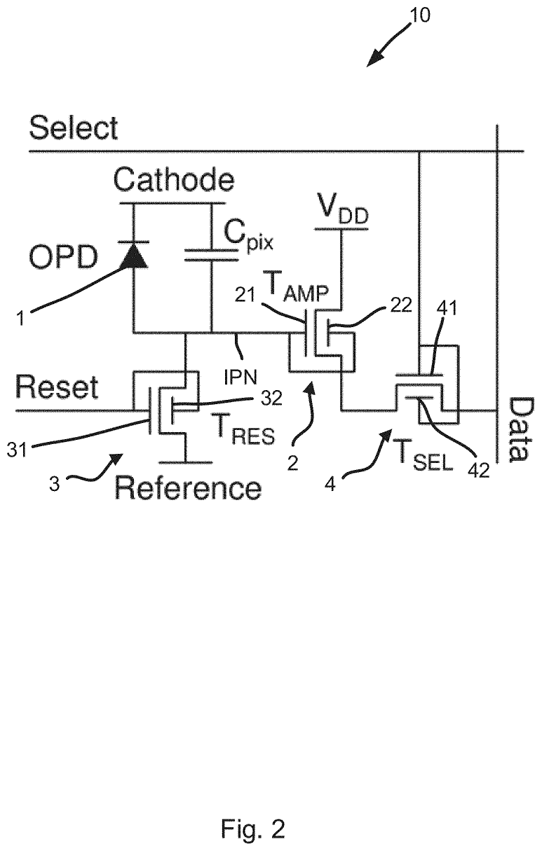

FIG. 2 illustrates the active thin-film charge sensor element 10 based on a voltage-mode 3T topology wherein back gates 22, 32 of the amplifier and the reset transistor 2, 3 are electrically connected to the front gates 21, 31 of the amplifier and reset transistor 2, 3. It can also be seen that a select transistor 4 may be electrically connected to the amplifier transistor 2, for example to a source or to a drain of the amplifier transistor 2, and in the illustrated example a front and back gate 41, 42 of the select transistor 4 are electrically connected.

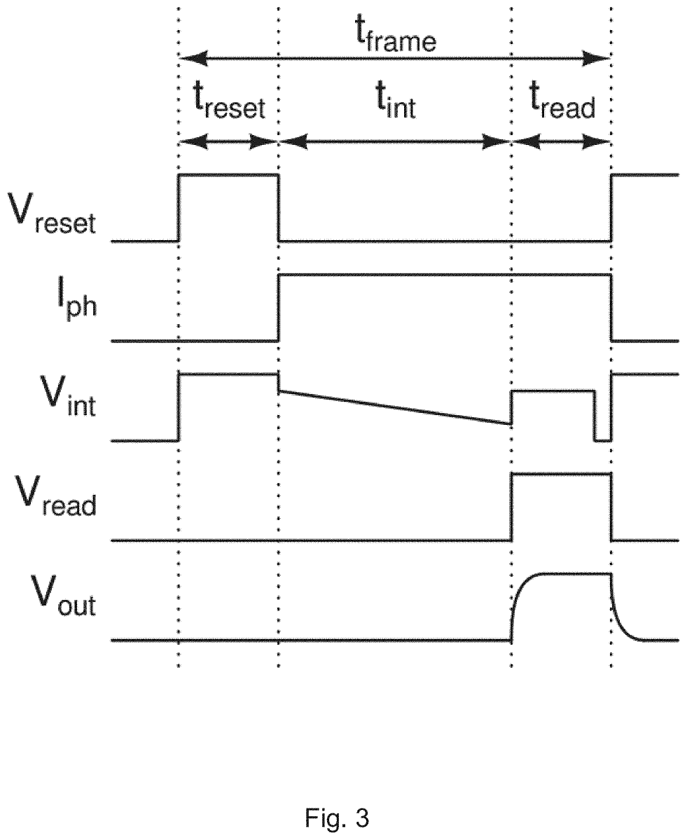

The operation of the 2T and 3T voltage-mode topology, discussed above, is illustrated in FIG. 3. FIG. 3 illustrates that initially a reset signal is high for a duration of time tᵣₑₛₑₜ. During that reset time tᵣₑₛₑₜ, a select signal is low resulting in a voltage level at the internal charge sensor element node IPN (at the front gate 21 of the amplifier transistor 2) being reset.

During an integration time tᵢₙₜ, both reset and select signals are low, and the detection of a physical quantity (e.g. electromagnetic radiation) by the charge collecting detector (e.g. an electromagnetic detector) 1 charges the charge sensor element capacitance C_{PIX}, thereby generating an intensity signal (voltage signal) at the internal charge sensor element node. When the integration time tᵢₙₜ is over, the select signal turns high and the intensity signal resulting from the detected physical quantity (e.g. electromagnetic radiation) by the charge collecting detector (e.g. electromagnetic detector) 1 is amplified by the amplifier transistor 2, thereby generating an output signal on the data line.

The operation is thus the same as today's voltage mode active charge sensor element sensors using transistors formed on a wafer substrate. It would therefore be possible to replace today's active charge sensor element sensors with a plurality of active thin-film charge sensor elements 10, since the drivers and/or logic do not need to be replaced but can be used with possibly minor adjustments.

The amplifier transistor 2 may be configured to be controlled by an adjustable voltage over time. By adjusting the voltage at the back gate 22 or at a source or a drain of the amplifier transistor 2, the amplifier transistor 2 can be controlled to amplify when desired. The adjustable voltage may originate from the select line. This allows for great flexibility and triggering of when the amplifier transistor 2 is to be conductive, i.e. when the amplifier transistor 2 is amplifying the intensity signal.

Additionally, a physical connection of the back gate 32, 42 of the reset transistor 3 or select transistor 4, or the back gate 22 of the amplifier transistor 2 can be connected externally to the individual active charge sensor elements 10, i.e. outside of the active charge sensor element 10, allowing for omitting a via that is normally needed to connect a back gate connection with a source-drain layer in other types of MOSFETs.

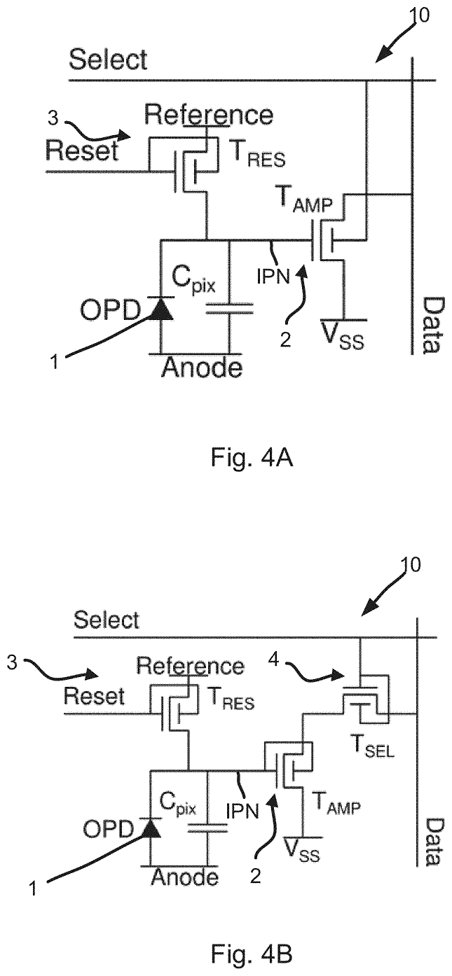

All effects and modes of operation that are discussed above for the 2T and 3T voltage mode topology also apply for the active thin-film charge sensor element 10 based on a current-mode 2T and 3T topology, illustrated in FIGS. 4A and 4B.

FIGS. 5A-5D further illustrate other 2T topologies based on the active thin-film charge sensor element 10. FIG. 5A illustrates a source follower topology (voltage mode topology), FIG. 5B illustrates a variation of this source follower topology, FIG. 5C illustrates a common source topology (current mode topology) and FIG. 5D illustrates a variation of this common source topology.

In the topologies illustrated in FIGS. 5B and 5D, an extra capacitance (C_{ST}) is omitted compared to the topologies illustrated in FIGS. 5A and 5C. This presence of a capacitance (C_{ST}) increases the size or area of the active charge sensor element 10 and reduces the sensitivity of the active charge sensor element 10. Thus, by omitting this capacitance (C_{ST}), the performance of the charge sensor element 10 is increased, and higher resolution charge-based sensors can be achieved. Depending on the physical implementation of the charge collecting detector, e.g. electromagnetic detector 1, the amplifier and reset transistors 2, 3 are electrically connected to an anode or cathode side of the electromagnetic detector 1.

For the topologies illustrated in FIGS. 5A-5D, a mode of operation may be that at a beginning of a readout cycle, the front or back gate 21, 22 of the amplifier transistor 2 is reset to a voltage on the data line.

During the integration time, a small current from the electromagnetic detector 1 is collected on the internal node capacitance C_{PIX}. In FIG. 5A, the voltage at the front and back gate 21, 22 will increase, whereas in FIG. 5C, the voltage will decrease. In either case, the voltage should stay below a threshold voltage (conduction limit) of the amplifier transistor 2 such that there is no amplification by the amplifier transistor 2, either as voltage or as current.

In the readout phase, a voltage and/or current pulse is applied on the select line. This will increase the voltage at the front and back gate 21, 22 of the amplifier transistor 2 due to the capacitive coupling caused by the capacitance C_{ST} on the select line.

The voltage at the front and back gate 21, 22 of the amplifier transistor 2 should now be above the threshold voltage of the amplifier transistor 2, and the amplifier transistor 2 is now active and amplifies the intensity signal.

The active thin-film charge sensor element 10, the amplifier transistor 2, and/or the reset transistor 3 may be based on an etch-stop layer, back-channel etch, and/or self-aligned transistor architecture.

As discussed above, a charge-based sensor, e.g. an image sensor, may comprise a plurality of active thin-film charge sensor elements, e.g. active thin-film pixels 10. The charge-based sensor may comprise rows and/or columns of the active thin-film charge sensor elements 10.

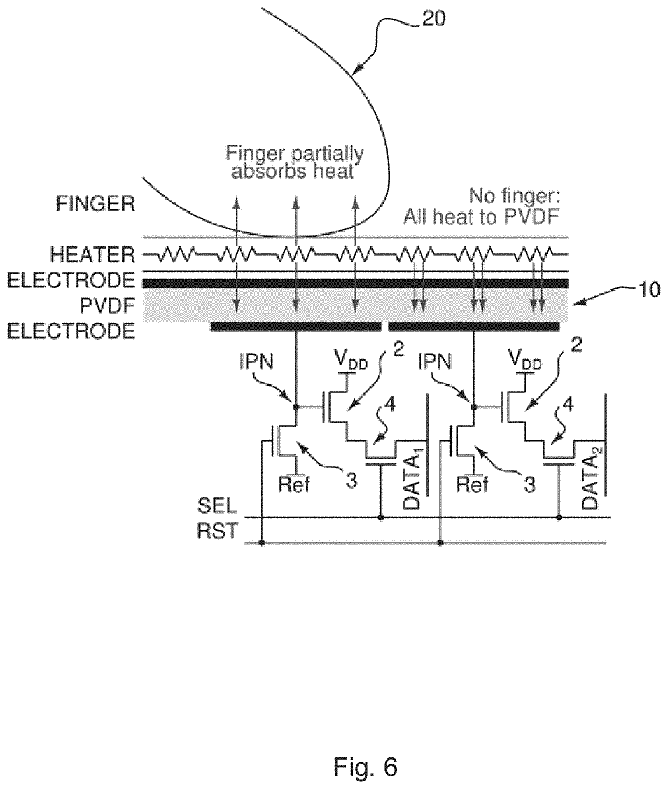

The active thin-film charge sensor element 10 may also be used in a fingerprint sensor. An example of such a fingerprint sensor is illustrated in FIG. 6. The fingerprint sensor may be of an active thermal or passive thermal type. In a passive thermal type of fingerprint sensor, the active thin-film charge sensor element 10 is configured to detect changes in temperature caused by a presence of a finger 20 and generate charges. After a while, the temperature of the active thin-film charge sensor element 10 settles to the temperature of the finger, and the generation of charges stops.

In an active fingerprint sensor type, a small quantum of heat Q_is injected at the same location as the active thin-film charge sensor element 10, and the local thermal mass is observed. When a fingerprint ridge is present, a higher thermal mass is observed, and a lower temperature increase ΔT is observed for a given heat Q, which then generates charges.

FIG. 6 illustrates a pyroelectric fingerprint sensor of an active type comprising of an array of active thin-film charge sensor elements 10. A pyroelectric layer will generate charges ΔQ depending on the temperature change ΔT:

ΔQ=pAΔT

Wherein A is the area of the layer and p is a material dependent pyroelectric coefficient. An example of the pyroelectric material is a Poly-VinylDiFluoride-TriFluoroEthylene (PVDF-TrFE), which is sometimes abbreviated as PVDF.

The pyroelectric material, PVDF, combined with the electrodes can be considered analogous to the OPD in FIGS. 1-5D and thus will generate charges on the internal sensor element node IPN.

As discussed above and illustrated in FIG. 6, when the finger is placed above the heater, the finger will partially absorb heat from the heater. The remaining heat will spread to the PVDF material and result in a lower generation of charges compared to other areas of the PVDF material where the finger is not present. By dividing an electrode layer on one side of the PVDF material into fixed size isolated areas it is possible to generate a matrix or array of active thin-film charge sensor elements 10 for finger detection over a surface such as a mobile phone screen. Hence, similar to optical large-area optical imagers, the active thin-film charge sensor elements 10 can be arranged in a large array.

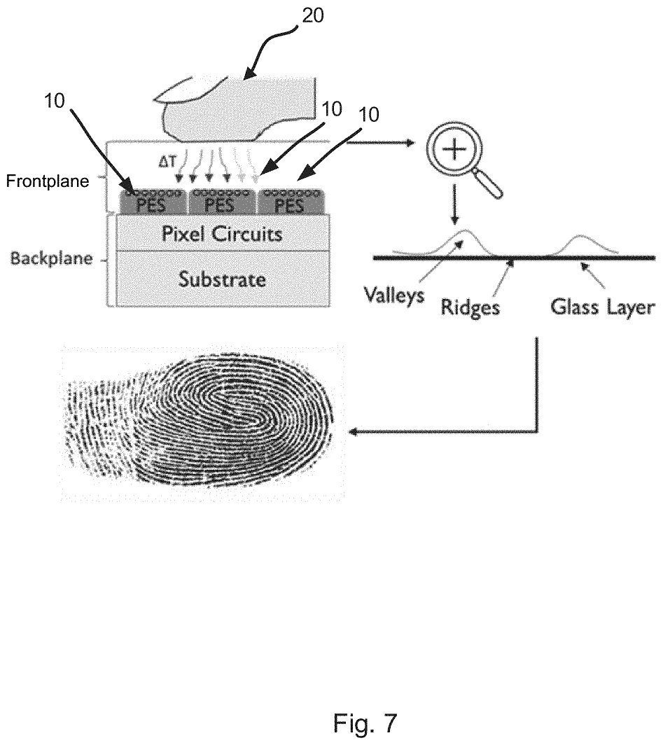

Illustrated in FIG. 7, the array of active thin-film charge sensor elements 10 is arranged in a front plane. The output of the front plane is a quantum of charge Q for each active thin-film charge sensor element 10, typically expressed in number of electrons. The collected charges are processed by a backplane, which consists of active thin-film charge sensor element 10 circuits and peripherals. A purpose of the backplane is to quantize the charges Q as accurate and fast as possible for the full array.

The charges may be further processed and possibly also similarly processed as discussed above in relation to optical imagers, i.e. the backplane is agnostic to how the charges are generated.

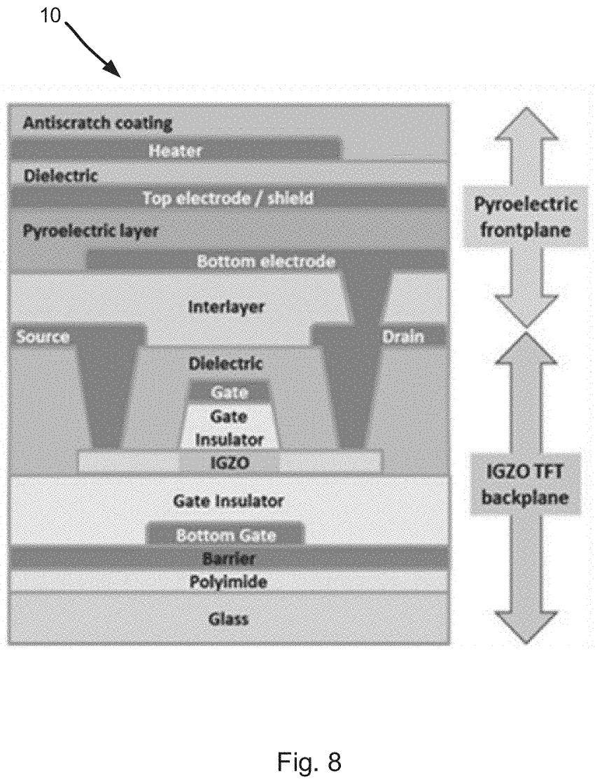

The front plane and backplane may be arranged as illustrated in FIG. 8. FIG. 8 illustrates a layer stack of the front plane and backplane of one active thin-film charge sensor element 10. This stack layer uses a soluble PVDF-based pyroelectric material as the active layer. In the active layer the temperature increase is translated into charges, which in turn creates a current that charges or discharges a node where the backplane and the bottom electrode are connected, depending on the polarity of the active thin-film charge sensor element 10.

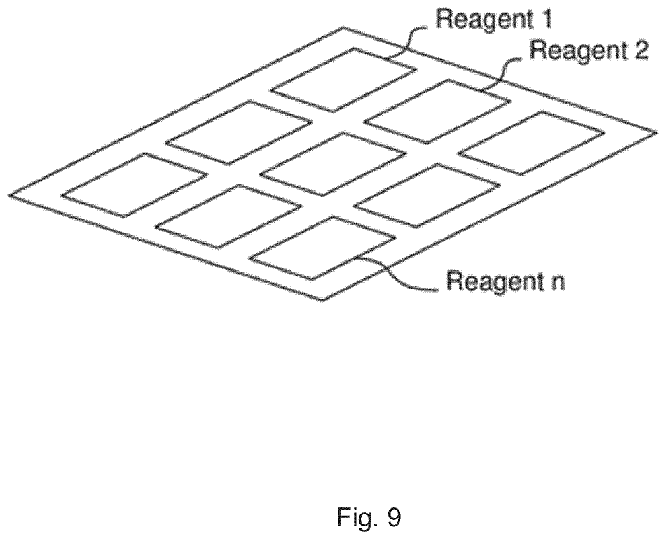

The active thin-film charge sensor element 10 may also be used in a biochemical detector application. The biochemical detector may comprise a plurality of active thin-film charge sensor elements 10 arranged in an array or matrix configuration also known as an assay, illustrated in FIG. 9.

The active thin-film charge sensor elements 10 in the assay may be doped or prepared with different detection chemicals, which react to different analytes and then generates charges. This allows for a sample to be analyzed having different types of molecules or analytes, of which the presence is to be detected.

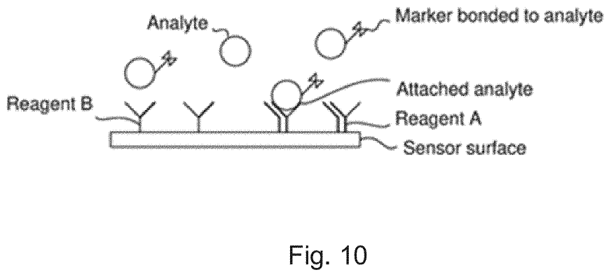

To ensure proper localization, the local reagent is fixed to the substrate in each sensor element (pixel), e.g. by chemically bonding to the surface there. There are several ways to measure whether a reaction has taken place at a specific site or pixel after the sample is applied to the assay. Most detection methods use some kind of marker which is attached to the molecules in the sample to indicate their presence. This marker can be a fluorescent complex or an electric charge. FIG. 10 illustrates a possible scenario at the surface of the at the active thin-film charge sensor element 10.

Two pixels are shown, one with reagent A, and the other with reagent B. The analyte bonds to reagent A only, bringing the marker close to the surface of the sensor.

After the sample is applied to the surface, the sample is cleaned and/or washed again, so that only the attached analytes remain at each pixel.

Depending on the type of the marker, different readout methodologies can be used. For a fluorescent marker, optical techniques can be used, like laser scanning, or an integrated optical sensor array, i.e. a large-area imager.

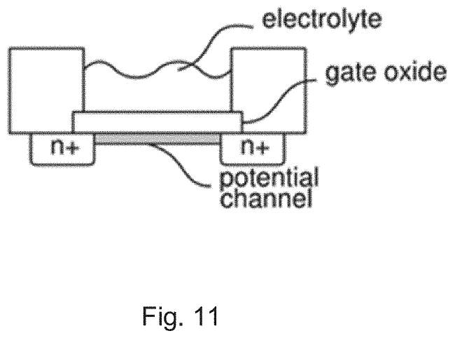

Illustrated in FIG. 11 is an example of a setup for an electrical readout when the marker is charged. A typical example of this concept is the ion-sensitive field-effect transistor (ISFET). An ISFET is typically used for measuring local pH, by checking the local charge caused by the acidity of the fluid. Here, this charge is used to bring a semiconductor in inversion or accumulation, thereby opening a FET channel.

Other types are e.g. the DNAFET, where DNA is matched with DNA strands fixed to the surface, and the intrinsic charge of the DNA is used to bias a gate of a nanowire transistor.

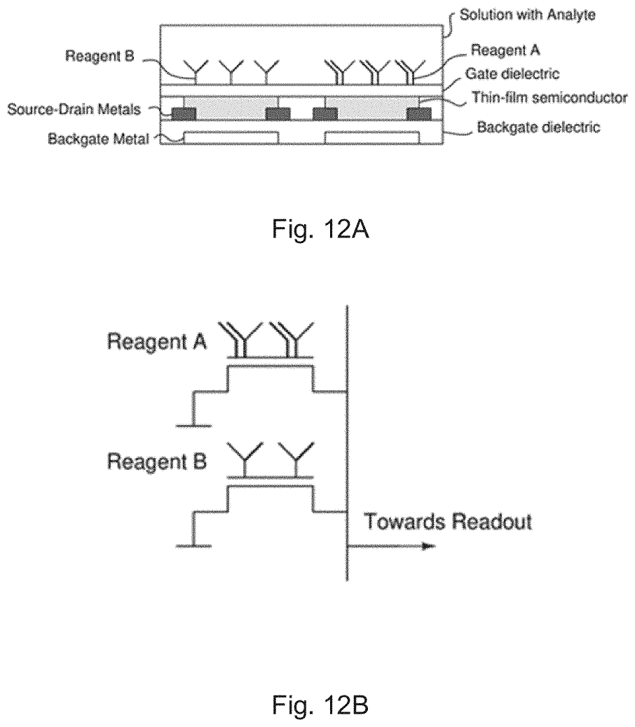

Another example based on the active thin-film charge sensor element 10 is a large-area platform comprising an array comprising a semiconductor material being a thin-film semiconductor. This would be another charge-based sensor, where it would be possible to measure charges on the internal node IND, but the internal node IND is a top surface of a DNA-covered surface. An example of this configuration is illustrated in FIGS. 12A and 12B.

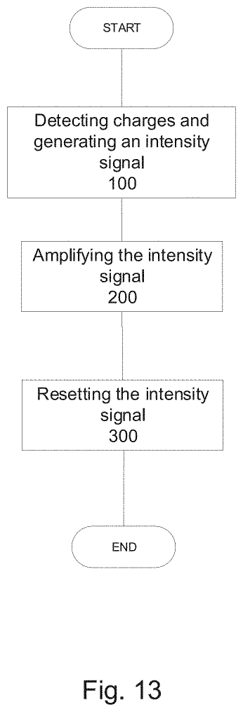

FIG. 13 illustrates a method for controlling the active thin-film charge sensor element 10. The method comprises detecting 100 a predetermined physical quantity with a charge collecting detector 1 of the charge sensor element 10 and generating a corresponding intensity signal at an internal charge sensor element node IND. The method comprises amplifying 200 the intensity signal by an amplifier transistor 2 comprising at least one gate that is electrically connected to the charge collecting detector 1 at the internal charge sensor element node IND.

The method comprises resetting 300 the intensity signal by a reset transistor 3, wherein the reset transistor is electrically connected to the internal charge sensor element node IND, and wherein the amplifying 200 and/or resetting 300 is controlled by a front gate and a back gate of the amplifier transistor 2 or reset transistor 3.

A reset signal may be applied to a gate of the amplifier transistor 2 for resetting the intensity signal.

From the description above follows that, although various examples of the disclosure have been described and shown, the disclosure is not restricted thereto, but may also be embodied in other ways within the scope of the subject-matter defined in the following claims. While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A charge sensor element comprising:
a charge collecting detector configured to generate an intensity signal indicative of an amount of charge at an internal charge sensor element node;
an amplifier transistor that is electrically connected to the internal charge sensor element node and configured to amplify the intensity signal; and
a reset transistor that is electrically connected to the internal charge sensor element node and configured to reset the intensity signal,
wherein the amplifier transistor or the reset transistor comprises a front gate and a back gate that are configured to control the amplifier transistor or the reset transistor.

2. The charge sensor element according to claim 1, wherein the amplifier transistor comprises the front gate and the back gate, and wherein the back gate of the amplifier transistor is electrically connected to the front gate or a select signal line.

3. The charge sensor element according to claim 1, wherein the reset transistor comprises the front gate and the back gate, and wherein the back gate of the reset transistor is electrically connected to the front gate of the reset transistor.

4. The charge sensor element according to claim 1, wherein each of the amplifier transistor and the reset transistor comprises the front gate and the back gate.

5. The charge sensor element according to claim 1, wherein the back gate of the amplifier transistor is configured to be controlled by an adjustable voltage.

6. The charge sensor element according to claim 1, further comprising a select transistor electrically connected to the amplifier transistor, wherein the select transistor comprises a front gate and a back gate, and wherein the front gate of the select transistor is electrically connected to the back gate of the select transistor.

7. The charge sensor element according to claim 1, wherein the reset transistor and the amplifier transistor are electrically connected to an anode or cathode of the charge collecting detector.

8. The charge sensor element according to claim 1, wherein the amplifier transistor and the reset transistor are based on an etch-stop layer, back-channel etch, and/or self-aligned transistor architecture.

9. The charge sensor element according claim 1, wherein the charge collecting detector comprises a photodetector.

10. The charge sensor element according claim 1, wherein the charge collecting detector comprises a pyroelectric sensor. an ion-sensitive field-effect transistor or a bio-sensitive field-effect transistor.

11. The charge sensor element according claim 1, wherein the charge collecting detector comprises an ion-sensitive field-effect transistor.

12. The charge sensor element according claim 1, wherein the charge collecting detector comprises a bio-sensitive field-effect transistor.

13. A charge sensor element array, comprising a plurality of the charge sensor element according to claim 1.

14. A method for controlling a charge sensor element, the method comprising:
generating, via a charge collecting detector, an intensity signal indicative of an amount of charge at an internal charge sensor element node;
amplifying the intensity signal via an amplifier transistor that is electrically connected to the charge collecting detector at the internal charge sensor element node; and
resetting the intensity signal via a reset transistor that is electrically connected to the internal charge sensor element node,
wherein the amplifying is controlled by a front gate and a back gate of the amplifier transistor or the resetting is controlled by a front gate and a back gate of the reset transistor.

15. The method according to claim 14, further comprising applying a select signal to the back gate of the amplifier transistor or the front gate of the amplifier transistor.

16. The method according to claim 14, wherein a signal applied to the back gate or the front gate of the amplifier transistor is varied over time.

17. The method according to claim 14, wherein a signal is applied to the back gate of the amplifying transistor and the front gate of the amplifier transistor.

18. The method according to claim 14 further comprising applying a reset signal to the front gate and the back gate of the reset transistor electrically connected to the charge collecting detector and the amplification transistor, for resetting the intensity signal.
